(19) United States
(12) Patent Application Publication
(10) Pub. No.: US 2024/0200195 A1
(43) Pub. Date: Jun. 20, 2024

(54) SUBSTRATE PROCESSING METHOD, SUBSTRATE PROCESSING APPARATUS, AND RECORDING MEDIUM

(71) Applicant: Tokyo Electron Limited, Tokyo (JP)

(72) Inventor: Takafumi Niwa, Kikuchi-gun, Kumamoto (JP)

(21) Appl. No.: 18/554,836

(22) PCT Filed: Apr. 1, 2022
(86) PCT No.: PCT/JP2022/016984

§ 371 Date: Oct. 11, 2023

(30) Foreign Application Priority Data
Apr. 15, 2021 (JP) 2021-068753

(51) Int. Cl. C23C 18/52; C23C 18/16; C23C 18/18

(52) U.S. Cl. CPC C23C 18/52; C23C 18/163; C23C 18/1675; C23C 18/1844

(57) ABSTRACT

A substrate processing method includes preparing a substrate, removing at least a part of a first metal layer, and precipitating a second metal layer. In the preparing of the substrate, the substrate having the first metal layer formed on a front surface thereof is prepared. In the removing of at least the part of the first metal layer, at least the part of the first metal layer formed on a peripheral portion of the substrate is removed. In the precipitating of the second metal layer, the second metal layer is precipitated on the front surface of the substrate by using the first metal layer as a catalyst after the removing of at least the part of the first metal layer.

### TECHNICAL FIELD

The various aspects and embodiments described herein pertain generally to a substrate processing method, a substrate processing apparatus, and a recording medium.

### BACKGROUND

Conventionally, as a way to form a multilayer wiring on a semiconductor wafer as a substrate, there is known a method of performing an electroless plating processing by using a copper seed layer formed in an inside of a via as a catalyst to fill the inside of the via with a copper wiring (see Patent Document 1).

### PRIOR ART DOCUMENT

Patent Document 1: Japanese Patent Laid-open Publication No. 2001-102448

### DISCLOSURE OF THE INVENTION

### Problems to be Solved by the Invention

Exemplary embodiments provide a technique for improving uniformity of the film thickness of a plating layer formed on a substrate.

### Means for Solving the Problems

In an exemplary embodiment, a substrate processing method includes preparing a substrate, removing at least a part of a first metal layer, and precipitating a second metal layer. In the preparing of the substrate, the substrate having the first metal layer formed on a front surface thereof is prepared. In the removing of at least the part of the first metal layer, at least the part of the first metal layer formed on a peripheral portion of the substrate is removed. In the precipitating of the second metal layer, the second metal layer is precipitated on the front surface of the substrate by using the first metal layer as a catalyst after the removing of at least the part of the first metal layer.

### Effect of the Invention

According to the exemplary embodiments, it is possible to improve the uniformity of the film thickness of the plating layer formed on the substrate.

### BRIEF DESCRIPTION OF THE DRAWINGS

FIG. 1 is a diagram illustrating a configuration of a substrate processing apparatus according to an exemplary embodiment.

FIG. 2 is a diagram illustrating a configuration of a plating unit according to the exemplary embodiment.

FIG. 3 is a diagram illustrating a configuration of a seed layer removing unit according to the exemplary embodiment.

FIG. 4 is an enlarged cross sectional view illustrating an example state of a peripheral portion of a substrate before being subjected to a substrate processing according to the exemplary embodiment.

FIG. 5 is a diagram for describing a removing processing according to the exemplary embodiment.

FIG. 6 is an enlarged cross sectional view illustrating an example state of the peripheral portion of the substrate after being subjected to the removing processing according to the exemplary embodiment.

FIG. 7 is a diagram for describing a rinsing processing according to the exemplary embodiment.

FIG. 8 is a diagram for describing a drying processing according to the exemplary embodiment.

FIG. 9 is a diagram illustrating film thickness distributions of plating layers in an experimental example and a reference example.

FIG. 10 is a flowchart illustrating a processing sequence in the substrate processing according to the exemplary embodiment.

FIG. 11 is a flowchart illustrating a processing sequence in a plating processing according to the exemplary embodiment.

### DETAILED DESCRIPTION

Hereinafter, exemplary embodiments of a substrate processing method, a substrate processing apparatus and a recording medium according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, as a way to form a multilayer wiring on a semiconductor wafer as a substrate, there is known a method of performing an electroless plating processing by using a copper seed layer formed in an inside of a via as a catalyst to fill the inside of the via with a copper wiring.

In the prior art, however, when the seed layer is formed on the substrate in a non-uniform manner, a supply of electrons required for precipitation of a plating layer may become non-uniform, which may have an adverse effect on the uniformity of the film thickness of the plating layer. This problem occurs conspicuously at, for example, a peripheral portion of the substrate where the seed layer is highly likely to be formed in a non-uniform manner.

In this regard, there is a demand for a technique capable of improving the uniformity of the film thickness of the plating layer formed on the substrate while overcoming the aforementioned problem.

### <Outline of Substrate Processing Apparatus>

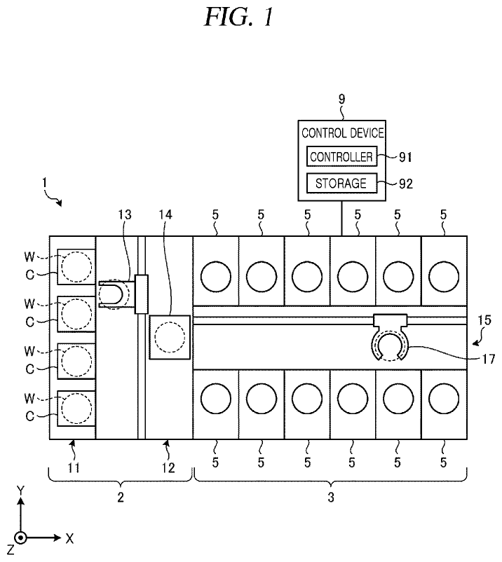

First, a schematic configuration of a substrate processing apparatus 1 according to an exemplary embodiment will be described with reference to FIG. 1. FIG. 1 is a diagram illustrating the configuration of the substrate processing apparatus 1 according to the exemplary embodiment. Further, in the following, in order to clarify positional relationships, the X-axis, the Y-axis and the Z-axis which are orthogonal to each other will be defined, and the positive Z-axis direction will be regarded as a vertically upward direction.

As shown in FIG. 1, the substrate processing apparatus 1 includes a carry-in/out station 2 and a processing station 3. The carry-in/out station 2 and the processing station 3 are provided adjacent to each other.

The carry-in/out station 2 is equipped with a carrier placing table 11 and a transfer section 12. On the carrier placing table 11, a plurality of carriers C is placed to horizontally accommodate a plurality of substrates, i.e., semiconductor wafers (hereinafter, also referred to as “substrates W”) in the present exemplary embodiment.

A plurality of load ports is arranged on the carrier placing table 11 so as to be adjacent to the transfer section 12, and the carriers C are placed on the load ports one by one.

The transfer section 12 is provided adjacent to the carrier placing table 11, and has a substrate transfer device 13 and a delivery unit 14 therein. The substrate transfer device 13 is equipped with a wafer holding mechanism configured to hold the substrate W. Further, the substrate transfer device 13 is movable in horizontal and vertical directions and pivotable around a vertical axis, and it serves to transfer the substrate W between the carrier C and the delivery unit 14 by using the wafer holding mechanism.

The processing station 3 is disposed adjacent to the transfer section 12. The processing station 3 is equipped with a transfer section 15 and a plurality of plating units 5. The plating unit 5 is an example of a metal layer forming unit. The plurality of plating units 5 is arranged at both sides of the transfer section 15. A configuration of the plating unit 5 will be described later.

The transfer section 15 has a substrate transfer device 17 therein. The substrate transfer device 17 is equipped with a wafer holding mechanism configure to hold the substrate W. Further, the substrate transfer device 17 is movable in horizontal and vertical directions and pivotable around a vertical axis, and it serves to transfer the substrate W between the delivery unit 14 and the plating unit 5 by using the wafer holding mechanism.

Further, the substrate processing apparatus 1 is equipped with a control device 9. The control device 9 is, for example, a computer, and includes a controller 91 and a storage 92. The storage 92 stores therein a program for controlling various processings performed in the substrate processing apparatus 1. The controller 91 controls the operation of the substrate processing apparatus 1 by reading and executing the program stored in the storage 92.

Furthermore, the program may have been recorded in a computer-readable recording medium, and may be installed from the recording medium to the storage 92 of the control device 9.

The computer-readable recording medium may be, by way of non-limiting example, a hard disk (HD), a flexible disk (FD), a compact disk (CD), a magnet optical disk (MO), a memory card, or the like.

In the substrate processing apparatus 1 configured as described above, the substrate transfer device 13 of the carry-in/out station 2 first takes out the substrate W from the carrier C placed in the carrier placing table 11, and places the taken substrate W in the delivery unit 14.

The wafer W placed in the delivery unit 14 is taken out from the delivery unit 14 by the substrate transfer device 17 of the processing station 3 and carried into the plating unit 5 to be processed by the plating unit 5.

For example, a barrier layer M0 (see FIG. 4) and a seed layer M1 (see FIG. 4) are stacked on a surface of the substrate W, and the plating unit 5 performs a plating layer forming processing on a surface of the seed layer M1 by an electroless plating method. The seed layer M1 is an example of a first metal layer, and the plating layer is an example of a second metal layer.

The substrate W processed by the plating unit 5 is carried out from the plating unit 5 by the substrate transfer device 17, and placed in the delivery unit 14. The substrate W placed in the delivery unit 14 after being finished with the processing is returned back into the carrier C of the carrier placing table 11 by the substrate transfer device 13.

### <Outline of Plating Unit>

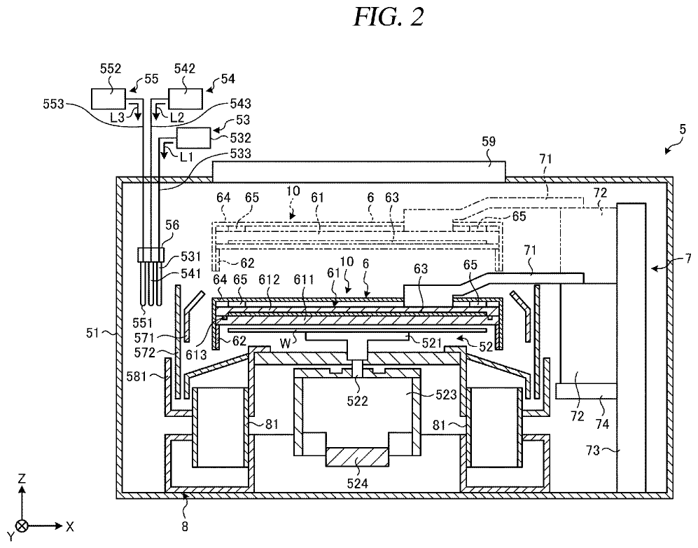

Now, a schematic configuration of the plating unit 5 will be explained with reference to FIG. 2. FIG. 2 is a diagram illustrating the configuration of the plating unit 5 according to the exemplary embodiment. For example, the plating unit 5 is configured as a single-wafer processing unit configured to process the substrates W one by one.

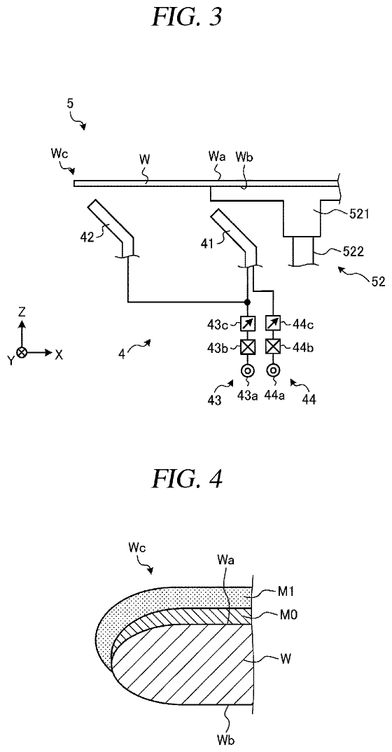

The plating unit 5 is configured to perform a liquid processing including an electroless plating processing. The plating unit 5 is equipped with a chamber 51, a substrate holder 52 disposed in the chamber 51 to hold the substrate W horizontally, and a plating liquid supply 53 configured to supply a plating liquid L1 to a front surface (top surface) Wa (see FIG. 3) of the substrate W held by the substrate holder 52.

In the exemplary embodiment, the substrate holder 52 has a chuck member 521 configured to vacuum-attract a rear surface (bottom surface) Wb (see FIG. 3) of the substrate W. The chuck member 521 is of a so-called vacuum chuck type.

A rotation motor 523 (rotational driving unit) is connected to the substrate holder 52 via a rotation shaft 522. When this rotation motor 523 is driven, the substrate holder 52 is rotated along with the substrate W. The rotation motor 523 is supported by a base 524 fixed to the chamber 51. Further, a heating source such as a heater is not provided inside the substrate holder 52.

The plating liquid supply 53 includes a plating liquid nozzle 531 configured to discharge (supply) the plating liquid L1 to the substrate W held by the substrate holder 52, and a plating liquid source 532 configured to supply the plating liquid L1 to the plating liquid nozzle 531. Here, the plating liquid source 532 is configured to supply the plating liquid L1 heated or regulated to a preset temperature to the plating liquid nozzle 531 through a plating liquid line 533.

The temperature of the plating liquid L1 when it is discharged from the plating liquid nozzle 531 is in the range of, e.g., 55° C. to 75° C., more desirably, in the range of 60° ° C. to 70° C. The plating liquid nozzle 531 is held by a nozzle arm 56, and is configured to be movable.

The plating liquid L1 is a plating liquid for autocatalytic (reduction type) electroless plating. The plating liquid L1 contains, for example, metal ions and a reducing agent. The metal ions contained in the plating liquid L1 may be, by way of non-limiting example, cobalt (Co) ions, nickel (Ni) ions, tungsten (W) ions, copper (Cu) ions, palladium (Pd) ions, gold (Au) ions, ruthenium (Ru) ions, or the like.

Further, the reducing agent contained in the plating liquid L1 may be, by way of non-limiting example, hypophosphorous acid, dimethyl amine borane, glyoxylic acid, or the like. The plating layer formed by the plating processing using the plating liquid L1 may be, for example, CoWB, CoB, CoWP, CoWBP, NiWB, NiB, NiWP, NiWBP, Cu, Pd, Ru, or the like.

In addition, the plating layer may be formed as a monolayer, or may be formed over two or more layers. When the plating layer has a two-layer structure, it may have a layer structure such as, but not limited to, CoWB/CoB or Pd/CoB stacked in sequence from the seed layer M1 (see FIG. 4) side.

The plating unit 5 further includes a cleaning liquid supply 54 configured to supply a cleaning liquid L2 to the surface of the substrate W held by the substrate holder 52, and a rinse liquid supply 55 configured to supply a rinse liquid L3 to the surface of the corresponding substrate W.

The cleaning liquid supply 54 supplies the cleaning liquid L2 to the substrate W held and being rotated by the substrate holder 52 to pre-clean the seed layer M1 formed on the substrate W. The cleaning liquid supply 54 includes a cleaning liquid nozzle 541 configured to discharge the cleaning liquid L2 to the substrate W held by the substrate holder 52, and a cleaning liquid source 542 configured to supply the cleaning liquid L2 to the cleaning liquid nozzle 541.

The cleaning liquid source 542 is configured to supply the cleaning liquid L2 heated or regulated to a predetermined temperature to the cleaning liquid nozzle 541 via a cleaning liquid line 543 as will be described later. The cleaning liquid nozzle 541 is held by the nozzle arm 56 to be movable along with the plating liquid nozzle 531.

As the cleaning liquid L2, dicarboxylic acid or tricarboxylic acid is used. The dicarboxylic acid may be, by way of non-limiting example, an organic acid such as malic acid, succinic acid, malonic acid, oxalic acid, glutaric acid, adipic acid, or tartaric acid. Further, as an example of the tricarboxylic acid, an organic acid such as citric acid may be used.

The rinse liquid supply 55 includes a rinse liquid nozzle 551 configured to discharge the rinse liquid L3 to the substrate W held by the substrate holder 52, and a rinse liquid source 552 configured to supply the rinse liquid L3 to the rinse liquid nozzle 551.

The rinse liquid nozzle 551 is held by the nozzle arm 56 to be movable along with the plating liquid nozzle 531 and the cleaning liquid nozzle 541. Further, the rinse liquid source 552 is configured to supply the rinse liquid L3 to the rinse liquid nozzle 551 via a rinse liquid line 553. As an example of the rinse liquid L3, DIW or the like may be used.

The nozzle arm 56 holding the plating liquid nozzle 531, the cleaning liquid nozzle 541, and the rinse liquid nozzle 551 described above is connected to a non-illustrated nozzle moving mechanism. This nozzle moving mechanism is configured to move the nozzle arm 56 in horizontal and vertical directions.

More specifically, the nozzle arm 56 is configured to be moved by the nozzle moving mechanism between a discharge position where the processing liquid (the plating liquid L1, the cleaning liquid L2 or the rinse liquid L3) is discharged to the substrate W and a retreat position where the nozzle arm 56 is retreated from the discharge position.

Here, the discharge position is not particularly limited as long as the processing liquid can be supplied to a certain position on the surface of the substrate W. By way of example, appropriately, the discharge position may be set such that the processing liquid can be supplied to the center of the substrate W.

The discharge position of the nozzle arm 56 may be different between the respective cases of supplying the plating liquid L1, the cleaning liquid L2, and the rinse liquid L3 to the substrate W. The retreat position is a position far from the discharge position without being overlapped with the substrate W, when viewed from above. When the nozzle arm 56 is placed at the retreat position, interference between this nozzle arm 56 and a cover body 6 being moved can be avoided.

A cup 571 is disposed around the substrate holder 52. This cup 571 is formed in a ring shape when viewed from above, receives the processing liquid scattered from the substrate W when the substrate W is rotated, and guides the received processing liquid to a drain duct 581.

An atmosphere blocking cover 572 is provided around the cup 571 to suppress diffusion of an atmosphere around the substrate W in the chamber 51. This atmosphere blocking cover 572 has a cylindrical shape extending in a vertical direction with an open top. The cover body 6 to be described later is configured to be inserted into the atmosphere blocking cover 572 from above.

In the exemplary embodiment, the substrate W held by the substrate holder 52 is covered by the cover body 6. This cover body 6 has a ceiling member 61 and a sidewall member 62 extending downwards from the ceiling member 61.

The ceiling member 61 includes a first ceiling plate 611, and a second ceiling plate 612 provided on top of the first ceiling plate 611. A heater 63 is interposed between the first ceiling plate 611 and the second ceiling plate 612. The first ceiling plate 611 and the second ceiling plate 612 are configured to seal the heater 63 so that the heater 63 does not come into contact with the processing liquid such as the plating liquid L1.

More specifically, a seal ring 613 is disposed around the heater 63, and the heater 63 is hermetically sealed by this seal ring 613. It is desirable that the first ceiling plate 611 and the second ceiling plate 612 have corrosion resistance to the processing liquid such as the plating liquid L1, and may be formed of, for example, an aluminum alloy. In order to improve the corrosion resistance, the first ceiling plate 611, the second ceiling plate 612, and the sidewall member 62 may be coated with Teflon (registered trademark).

A cover body moving mechanism 7 is connected to the cover body 6 via a cover body arm 71. The cover body moving mechanism 7 is configured to move the cover body 6 in horizontal and vertical directions. More specifically, the cover body moving mechanism 7 has a rotating motor 72 configured to move the cover body 6 in the horizontal direction and a cylinder 73 configured to move the cover body 6 in the vertical direction.

Here, the rotating motor 72 is mounted on a supporting plate 74 provided so as to be vertically movable with respect to the cylinder 73. Instead of the cylinder 73, an actuator (not shown) including a motor and a ball screw may be used.

The rotating motor 72 of the cover body moving mechanism 7 moves the cover body 6 between an upper position disposed above the substrate W held by the substrate holder 52 and a retreat position retreated from the upper position. Here, the upper position is a position facing the substrate W held by the substrate holder 52 at a relatively large distance therebetween, and is a position overlapping the substrate W when viewed from above.

The retreat position is a position within the chamber 51 that does not overlap the substrate W when viewed from above. When the cover body 6 is located at the retreat position, interference between the nozzle arm 56 being moved and the cover body 6 is avoided. A rotational axis of the rotating motor 72 extends in the vertical direction, and the cover body 6 can be pivoted in the horizontal direction between the upper position and the retreat position.

The cylinder 73 of the cover body moving mechanism 7 moves the cover body 6 in the vertical direction to adjust a distance between the substrate W supplied with the plating liquid L1 and the first ceiling plate 611 of the ceiling member 61. More specifically, the cylinder 73 locates the cover body 6 at a lower position (a position indicated by a solid line in FIG. 2) or the upper position (a position indicated by a dashed double-dotted line in FIG. 2).

In the exemplary embodiment, the heater 63 is driven to heat the substrate holder 52 or the plating liquid L1 on the substrate W when the cover body 6 is located at the above-described lower position.

The ceiling member 61 and the sidewall member 62 of the cover body 6 are covered with a cover body cover 64. This cover body cover 64 is disposed on the second ceiling plate 612 of the cover body 6 with a plurality of supporting members 65 therebetween. That is, on the second ceiling plate 612, the plurality of supporting members 65 protruding upwards from a top surface thereof is provided, and the cover body cover 64 is disposed on these supporting members 65.

The cover body cover 64 is configured to be movable in the horizontal direction and the vertical direction along with the cover body 6. Further, it is desirable that the cover body cover 64 has heat insulation property higher than those of the ceiling member 61 and the sidewall member 62 in order to suppress heat within the cover body 6 from escaping to the vicinity thereof. For example, it is desirable that the cover body cover 64 is made of a resin material, and it is more desirable that the resin material has heat resistance.

In the exemplary embodiment as described above, the cover body cover 64 and the cover body 6 equipped with the heater 63 are formed as one body. The cover body 6 and the cover body cover 64 constitutes a cover unit 10 which is configured to cover the substrate holder 52 or the substrate W when it is located at the lower position.

Above the chamber 51, there is provided a fan filter unit 59 configured to supply clean air near the cover body 6. The fan filter unit 59 supplies air into the chamber 51 (in particular, into the atmosphere blocking cover 572), and the supplied air flows toward an exhaust line 81.

A downflow of the air flowing downwards is formed around the cover body 6, and a gas vaporized from the processing liquid such as the plating liquid L1 flows toward the exhaust line 81 by being carried with this downflow. Accordingly, the gas vaporized from the processing liquid is suppressed from rising and diffusing into the chamber 51.

The gas supplied from the above-described fan filter unit 59 is exhausted by an exhaust mechanism 8.

### <Configuration of Seed Layer Removing Unit>

The plating unit 5 according to the exemplary embodiment further includes a seed layer removing unit 4 configured to remove a part of the seed layer M1 (see FIG. 4) formed on the front surface Wa of the substrate W. Now, a configuration of this seed layer removing unit 4 will be described with reference to FIG. 3. FIG. 3 is a diagram illustrating the configuration of the seed layer removing unit 4 according to the exemplary embodiment.

As depicted in FIG. 3, the seed layer removing unit 4 includes a first nozzle 41, a second nozzle 42, a removing liquid supply 43, and a rinse liquid supply 44. The first nozzle 41 and the second nozzle 42 are an example of a removing liquid discharge unit.

The first nozzle 41 is disposed below the substrate W held by the chuck member 521, and is configured to discharge the processing liquid toward the rear surface Wb of the substrate W. In the exemplary embodiment, the first nozzle 41 discharges the processing liquid to a position on the substrate W inside the peripheral portion Wc in a direction inclined outwards in a radial direction of the substrate W.

The second nozzle 42 is disposed below the substrate W held by the chuck member 521, and is configured to discharge the processing liquid toward the rear surface Wb of the substrate W. In the exemplary embodiment, the second nozzle 42 discharges the processing liquid to the peripheral portion Wc of the substrate W in a direction inclined outwards in the radial direction of the substrate W.

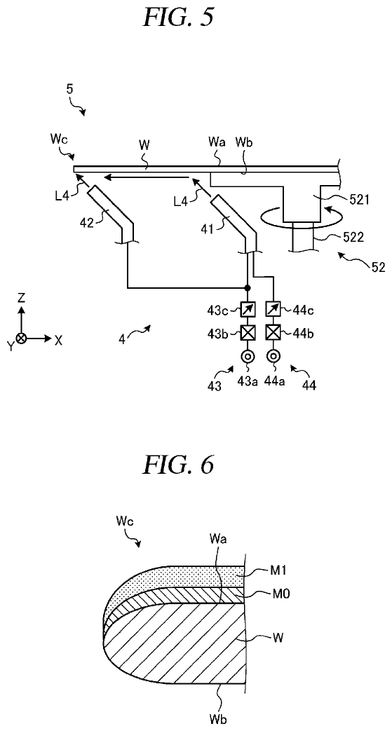

The removing liquid supply 43 is configured to supply a removing liquid L4 (see FIG. 5) to the first nozzle 41 and the second nozzle 42. The removing liquid L4 is a chemical liquid capable of removing the seed layer M1 formed on the front surface Wa of the substrate W.

By way of non-limiting example, a SPM (a mixed solution of sulfuric acid and hydrogen peroxide), a mixed solution of organic acid and hydrogen peroxide, a FPM (a mixed solution of hydrofluoric acid and hydrogen peroxide), an APM (a mixed solution of ammonium hydroxide and hydrogen peroxide solution), or the like may be used as the removing liquid L4.

The removing liquid supply 43 has a removing liquid source 43a, a valve 43b, and a flow rate controller 43c. The removing liquid source 43a supplies the removing liquid L4 to the first nozzle 41 and the second nozzle 42 via the valve 43b and the flow rate controller 43c. The flow rate controller 43c adjusts the flow rate of the removing liquid L4 supplied to the first nozzle 41 and the second nozzle 42.

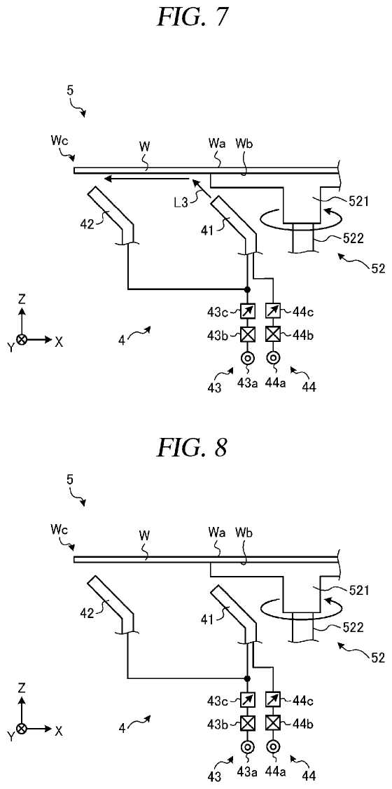

The rinse liquid supply 44 is configured to supply the rinse liquid L3 (see FIG. 7) to the first nozzle 41. The rinse liquid supply 44 has a rinse liquid source 44a, a valve 44b, and a flow rate controller 44c.

The rinse liquid source 44a supplies the rinse liquid L3 to the first nozzle 41 via the valve 44b and the flow rate controller 44c. The flow rate controller 44c adjusts the flow rate of the rinse liquid L3 supplied to the first nozzle 41.

### Exemplary Embodiment

Now, details of a substrate processing according to the exemplary embodiment will be described with reference to FIG. 4 to FIG. 9. FIG. 4 is an enlarged cross sectional view showing an example state of the peripheral portion Wc of the substrate W before being subjected to the substrate processing according to the exemplary embodiment.

Further, non-illustrated devices are already formed on the substrate W shown in FIG. 4. Hereinafter, various kinds of processings of forming a plating layer on the substrate W in a wiring forming process (so-called BEOL (Back End of Line)) after the formation of those devices will be described.

As shown in FIG. 4, the barrier layer M0 and the seed layer M1 are formed on the entire front surface Wa of the substrate W, including the peripheral portion Wc. Then, the substrate W having the barrier layer M0 and the seed layer M1 stacked on the front surface Wa thereof is carried into the above-described plating unit 5 to be subjected to an electroless plating processing.

The barrier layer M0 has a function of suppressing atoms contained in the seed layer M1 and the plating layer from being diffused into the substrate W made of silicon or the like. As an example of the barrier layer M0, Ta or TaN may be used. In the example of FIG. 4, the barrier layer M0 is illustrated as a single layer. However, the present disclosure is not limited thereto, and the barrier layer M0 may have a multilayer structure.

The seed layer M1 functions as a catalyst when precipitating the plating layer on the surface of the substrate W. As an example of the seed layer M1, a metal such as copper, cobalt, tungsten, ruthenium, or nickel, or an alloy containing one of these elements as a main component may be used.

This seed layer M1 is formed on the front surface Wa of the substrate W by, for example, a dry process such as a PVD (Physical Vapor Deposition) method or a CVD (Chemical Vapor Deposition) method.

Since it is difficult to match process conditions for the peripheral portion Wc of the substrate W with those for other portions, the film thickness of the seed layer M1 may become non-uniform at the peripheral portion Wc, and the seed layer M1 may become so thick that it may protrude outwards from a bevel portion of the substrate W, as shown in FIG. 4, for example.

When the plating layer is formed by the electroless plating processing on the front surface Wa of the substrate W whose state is as illustrated in FIG. 4, the peripheral portion Wc may be supplied with more electrons than the other portions of the substrate W from the seed layer M1, which raises a likelihood that the film thickness of the plating layer at the peripheral portion Wc may become thicker than that in the other portions. That is, when the plating layer is formed on the front surface Wa of the substrate W having the state as shown in FIG. 4 by the electroless plating processing, the uniformity of the film thickness of the plating layer may be adversely affected.

To solve the problem, in the exemplary embodiment, a removing processing of removing a part of the seed layer M1 is performed in the plating unit 5 prior to the electroless plating processing. FIG. 5 is a diagram for explaining the removing processing according to the exemplary embodiment.

As shown in FIG. 5, in the substrate processing method according to the exemplary embodiment, the controller 91 (see FIG. 1) first controls the substrate holder 52 to rotate the substrate W at a predetermined rotational speed. Further, the controller 91 controls the seed layer removing unit 4 to discharge the removing liquid L4 to the rear surface Wb of the substrate W from the first nozzle 41 and the second nozzle 42.

In this way, the controller 91 removes the seed layer M1 formed on the front surface Wa side of the peripheral portion Wc of the substrate W by using the removing liquid L4. By this removing processing, the seed layer M1 attached to the bevel portion of the substrate W or the like in a non-uniform manner is removed, as shown in FIG. 6. FIG. 6 is an enlarged cross sectional view showing an example state of the peripheral portion Wc of the substrate W after being subjected to the removing processing according to the exemplary embodiment.

That is, in the exemplary embodiment, the uniformity of the film thickness of the seed layer M1 formed on the front surface Wa of the substrate W can be improved through this removing processing.

In the exemplary embodiment, by enhancing the uniformity of the film thickness of the seed layer M1 formed on the front surface Wa of the substrate W, the uniformity of the film thickness of the plating layer formed in the electroless plating processing to described later can be improved. This is because, by enhancing the uniformity of the film thickness of the seed layer M1, the amount of electrons supplied from this seed layer M1 can be substantially equalized over the entire substrate W including the peripheral portion Wc.

That is, in the exemplary embodiment, by performing the removing processing of removing the part of the seed layer M1 prior to the electroless plating processing, the uniformity of the film thickness of the plating layer can be improved.

Further, in the exemplary embodiment, the seed layer M1 formed on the front surface Wa side of the peripheral portion Wc of the substrate W may be removed just by discharging the removing liquid L4 to the rear surface Wb of the substrate W. Thus, the seed layer M1 which is necessary for the electroless plating processing may be suppressed from being removed from the front surface Wa of the substrate W, while the unnecessary seed layer M1 which is attached to the bevel portion of the substrate W may be removed efficiently.

Therefore, according to the exemplary embodiment, the uniformity of the film thickness of the plating layer formed on the substrate W may be further enhanced.

In the exemplary embodiment, the removing liquid L4 may be directly discharged to the peripheral portion Wc of the substrate W by using the second nozzle 42 together with the first nozzle 41. As a result, the unnecessary seed layer M1 attached to the bevel portion of the substrate W or the like can be removed with high precision. Therefore, according to the exemplary embodiment, the uniformity of the film thickness of the plating layer formed on the substrate W may be further bettered.

Moreover, although FIG. 5 illustrates the example of removing the part of the seed layer M1 by discharging the removing liquid L4 to the rear surface Wb of the substrate W, the present disclosure is not limited thereto. By way of example, at least a part of the seed layer M1 formed on the peripheral portion Wc of the substrate W may be removed by discharging the removing liquid L4 to the peripheral portion Wc from the front surface Wa side of the substrate W.

In addition, at least a part of the seed layer M1 formed on the peripheral portion Wc of the substrate W may be removed by performing a dry etching processing on the peripheral portion Wc, using a processing unit (not shown) different from the plating unit 5.

Meanwhile, in the exemplary embodiment, by performing the removing processing and the electroless plating processing in the same processing unit (plating unit 5), the time required to transfer the substrate W between different processing units can be saved, so that the overall processing time for the substrate W can be shortened.

Now, various processings following the removing processing will be explained. In the exemplary embodiment, a rinsing processing of washing away the removing liquid L4 is performed after the removing processing. FIG. 7 is a diagram for describing the rinsing processing according to the exemplary embodiment.

As shown in FIG. 7, the controller 91 (see FIG. 1) controls the substrate holder 52 to rotate the substrate W at a predetermined rotational speed, and also controls the seed layer removing unit 4 to discharge the rinse liquid L3 to the rear surface Wb of the substrate W from the first nozzle 41. As a result, the controller 91 washes away the removing liquid L4 adhering to the rear surface Wb of the substrate W by using the rinse liquid L3.

Next, as shown in FIG. 8, the controller 91 (see FIG. 1) controls the substrate holder 52 to rotate the substrate W at a predetermined rotational speed to perform a drying processing on the substrate W. As a result, the rinse liquid L3 adhering to the substrate W is removed.

In the exemplary embodiment, since the removing liquid L4 can be removed from the substrate W by performing the rinsing processing and the drying processing after the removing processing, the necessary seed layer M1 can be suppressed from being removed by the removing liquid L4 remaining on the substrate W. Therefore, according to the exemplary embodiment, an appropriate plating layer can be formed in the electroless plating processing.

Further, in the exemplary embodiment, an inert gas may be discharged to the front surface Wa side of the substrate W during the removing processing, the rinsing processing, and the drying processing described so far. This suppresses the seed layer M1 from being oxidized before the electroless plating processing. Therefore, according to the exemplary embodiment, an appropriate plating layer can be formed in the electroless plating processing.

Subsequently, the substrate W held by the substrate holder 52 is subjected to a cleaning processing. In this case, first, the rotation motor 523 is driven to rotate the substrate W at a predetermined rotational speed. Then, the nozzle arm 56 located at the retreat position (the position indicated by the solid line in FIG. 2) is moved to the discharge position above the center of the substrate W.

Next, the cleaning liquid L2 is supplied from the cleaning liquid nozzle 541 to the substrate W being rotated, so that the front surface Wa of the substrate W is cleaned. As a result, deposits and the like adhering to the substrate W are removed from the substrate W. The cleaning liquid L2 supplied to the substrate W is drained into the drain duct 581.

Thereafter, the substrate W after being subjected to the cleaning processing is rinsed. In this case, the rinse liquid L3 is supplied from the rinse liquid nozzle 551 to the substrate W being rotated, so that the front surface Wa of the substrate W is rinsed. As a result, the cleaning liquid L2 remaining on the substrate W is washed away. The rinse liquid L3 supplied to the substrate W is drained into the drain duct 581.

Subsequently, the plating liquid L1 is supplied to be accumulated on the rinsed substrate W. In this case, first, the rotational speed of the substrate W is lowered than the rotational speed in the rinsing processing. For example, the rotational speed of the substrate W may be set to be in the range of 50 rpm to 150 rpm. As a result, the plating layer formed on the substrate W can be made uniform. Also, the rotation of the substrate W may be stopped.

Subsequently, the plating liquid L1 is discharged onto the surface of the substrate W from the plating liquid nozzle 531. The discharged plating liquid L1 stays on the surface of the substrate W due to a surface tension, and the plating liquid L1 is accumulated on the front surface Wa of the substrate W, so that a layer (so-called puddle) of the plating liquid L1 is formed.

Some of the plating liquid L1 is flown out from the surface of the substrate W to be drained into the drain duct 581. After a preset amount of the plating liquid L1 is discharged from the plating liquid nozzle 531, the discharge of the plating liquid L1 is stopped. Thereafter, the nozzle arm 56 located at the discharge position is placed at the retreat position.

Subsequently, the plating liquid L1 accumulated on the substrate W is heated. First, the substrate W is covered by the cover body 6. In this case, the rotating motor 72 of the cover body moving mechanism 7 is first driven, so that the cover body 6 is pivoted in the horizontal direction and placed at the upper position (the position indicated by the dashed double-dotted line in FIG. 2).

Then, the cylinder 73 of the cover body moving mechanism 7 is driven, so that the cover body 6 located at the upper position is lowered to be placed at the processing position. As a result, the distance between the plating liquid L1 on the substrate W and the first ceiling plate 611 of the cover body 6 becomes a preset distance, and the sidewall portion 62 of the cover body 6 is disposed around the substrate W.

In the present exemplary embodiment, a lower end of the sidewall portion 62 of the cover body 6 is positioned lower than the bottom surface of the substrate W. In this way, the substrate W is covered by the cover body 6, and a space around the substrate W is closed.

Then, a heating processing is performed. Specifically, the heater 63 is turned on to heat the plating liquid L1 accumulated on the substrate W. For example, a set temperature of the heater 63 is fixed to a constant target temperature through the heating processing. When the temperature of the plating liquid L1 rises up to a temperature at which components of the plating liquid L1 are precipitated, the components of the plating liquid L1 are precipitated on the surface of the seed layer M1 to form the plating layer.

Subsequently, a cover body retreating processing is performed. In the cover body retreating processing, the cover body moving mechanism 7 is driven to place the cover body 6 at the retreat position. In this case, as the cylinder 73 of the cover body moving mechanism 7 is first driven, the cover body 6 is raised to be placed at the upper position. Thereafter, the rotating motor 72 of the cover body moving mechanism 7 is driven, so that the cover body 6 located at the upper position is pivoted in the horizontal direction to be placed at the retreat position.

Next, the substrate W is subjected to a rinsing processing. In this case, first, the rotational speed of the substrate W is increased to be higher than the rotational speed in the plating processing. For example, the substrate W is rotated at the same rotational speed as in the rinsing processing that is performed on the front surface Wa before the plating processing.

Subsequently, the rinse liquid nozzle 551 located at the retreat position is moved to the discharge position. Then, the rinse liquid L3 is supplied from the rinse liquid nozzle 551 to the substrate W being rotated, so that the surface of the substrate W is cleaned. As a result, the plating liquid L1 remaining on the substrate W is washed away.

Then, the rinsed substrate W is subjected to a drying processing. In this case, the rotational speed of the substrate W is increased from the rotational speed in the rinsing processing that is performed immediately before, and the substrate W is rotated at a high speed. As a result, the rinse liquid L3 remaining on the substrate W is shaken off the substrate W, so that the substrate W is dried.

Upon the completion of the drying processing, the substrate W is taken out of the plating unit 5 and transferred to the delivery unit 14 by the substrate transfer device 17. Then, the substrate W transferred to the delivery unit 14 is taken out of the delivery unit 14 by the substrate transfer device 13 and accommodated in the carrier C, which ends the series of processes of the substrate processing for the single sheet of substrate W.

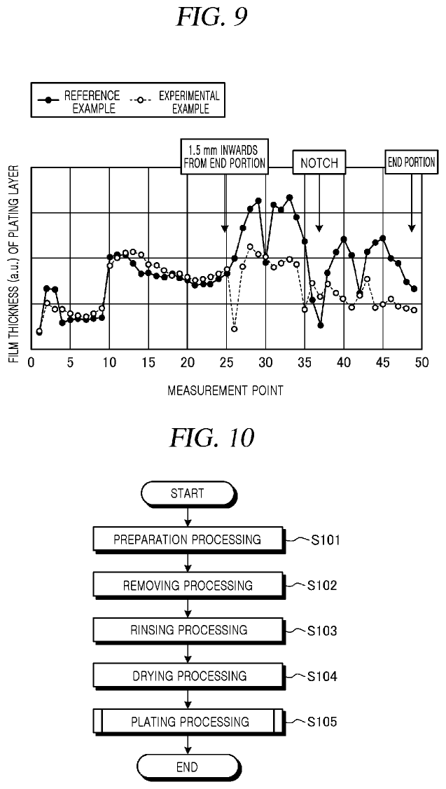

FIG. 9 is a diagram showing film thickness distributions of plating layers in an experimental example and a reference example. In the reference example shown in FIG. 9, the plating layer is formed under the same conditions as in the experimental example, except that the above-described removing processing is not performed.

In addition, graphs of FIG. 9 indicate film thickness distributions when a measurement point is gradually moved from an inner side toward an outer side. A measurement point 25 corresponds to a position of 1.5 mm inwards from an end portion of the substrate W; a measurement point 49 corresponds to a position of the end portion of the substrate W. Further, in the graphs of FIG. 9, a measurement point 37 corresponds to a position of a notch of the substrate W.

As shown in FIG. 9, in the experimental example and the reference example, the film thickness of the plating layer from the inner side to the peripheral portion Wc of the substrate W is almost uniform, exhibiting a good level of uniformity.

However, in the reference example, the film thickness of the plating layer at the peripheral portion Wc is found to be thicker than that of the inner side, resulting in a high level of non-uniformly. In the reference example, the non-uniformity of the film thickness of the plating layer on the entire substrate W is found to be about 2.6%.

Meanwhile, in the experimental example in which the seed layer M1 is removed prior to the electroless plating processing, the uniformity of the film thickness of the plating layer at the peripheral portion Wc is found to be improved as compared to that in the reference example, as shown in FIG. 9. In the experimental example, the non-uniformity of the film thickness of the plating layer on the entire substrate W is found to be about 1.8%.

Although the above exemplary embodiment has been described for the example where the plating layer is formed by the electroless plating processing, the present disclosure is not limited thereto, and the plating layer may be formed by, for example, an electrolytic plating processing. Even in the case of forming the plating layer by the electrolytic plating processing, if the film thickness of the seed layer M1 becomes non-uniform, the supply state of electrons from the outside may become non-uniform, which may have adverse effect on the film thickness of the plating layer, the same as in the above-described exemplary embodiment.

Therefore, by performing the removing processing of removing the part of the seed layer M1 of the peripheral portion Wc prior to the electrolytic plating processing, the uniformity of the film thickness of the plating layer formed on the substrate W can be improved.

The substrate processing apparatus 1 according to the exemplary embodiment includes the substrate holder 52, the removing liquid discharge unit (the first nozzle 41 and the second nozzle 42), the metal layer forming unit (the plating unit 5), and the controller 91. The substrate holder 52 holds the substrate W rotatably. The removing liquid discharge unit (the first nozzle 41 and the second nozzle 42) discharge the removing liquid L4 capable of removing the first metal layer (the seed layer M1) to the rear surface Wb of the substrate W. The metal layer forming unit (plating unit 5) forms the second metal layer (the plating layer) on the front surface Wa of the substrate W. The controller 91 controls the individual components. Further, the controller 91 holds, by the substrate holder 52, the substrate W having the first metal layer (the seed layer M1) formed on the front surface Wa. In addition, the controller 91 removes at least a part of the first metal layer (the seed layer M1) formed at the peripheral portion Wc of the substrate W by using the removing liquid discharge unit (the first nozzle 41 and the second nozzle 42). Further, the controller 91 precipitates, by using the metal layer forming unit (plating unit 5), the second metal layer (plating layer) on the front surface Wa of the substrate W with the first metal layer (seed layer M1) as a catalyst. As a result, the uniformity of the film thickness of the plating layer formed on the substrate W can be improved.

### <Details of Substrate Processing>

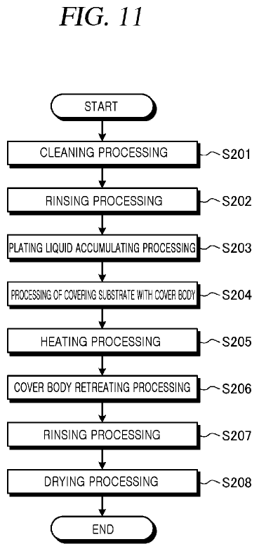

Now, referring to FIG. 10 and FIG. 11, details of the substrate processing performed by the substrate processing apparatus 1 according to the exemplary embodiment will be described. FIG. 10 is a flowchart showing a processing sequence of the substrate processing according to the exemplary embodiment.

First, the controller 91 controls the substrate transfer devices 13 and 17 to carry the substrate W into the plating unit 5 from the carrier C, and controls the substrate holder 52 to hold the substrate W, thus getting the substrate W ready to be processed (process S101).

Then, the controller 91 performs the removing processing on the substrate W (process S102). In this case, the rotation motor 523 is first driven to rotate the substrate W at a predetermined rotational speed. Then, the removing liquid L4 is discharged from the first nozzle 41 and the second nozzle 42 onto the substrate W being rotated to be supplied to the rear surface Wb of the substrate W.

As a result, at least a part of the seed layer M1 formed on the peripheral portion Wc of the substrate W is removed. The removing liquid L4 supplied to the substrate W is drained into the drain duct 581.

Thereafter, the controller 91 performs the rinsing processing on the substrate W (process S103). In this case, the rotation motor 523 is first driven to rotate the substrate W at a predetermined rotational speed. Then, the rinse liquid L3 is discharged from the first nozzle 41 onto the substrate W being rotated to be supplied to the rear surface Wb of the substrate W.

As a result, the removing liquid L4 adhering to the rear surface Wb of the substrate W is washed away. The rinse liquid L3 supplied to the substrate W is drained into the drain duct 581.

Afterwards, the controller 91 performs the drying processing on the substrate W (process S104). In this case, for example, the controller 91 increases the rotational speed of the substrate W from the rotational speed in the rinsing processing (process S103) to thereby rotate the substrate W at a high speed. As a result, the rinse liquid L3 remaining on the surface of the substrate W is shaken off, and the substrate W is dried.

Thereafter, the controller 91 performs the plating processing on the substrate W (process S104). For example, the plating layer is precipitated by using the seed layer M1 formed on the front surface Wa of the substrate W as the catalyst, so that the plating layer is formed on the front surface Wa of the substrate W. Details of this plating processing will be described later.

Upon the completion of the plating processing, the substrate W is taken out of the plating unit 5 and transferred to the delivery unit 14 by the substrate transfer device 17. The substrate transferred to the delivery unit 14 is then taken out of the delivery unit 14 by the substrate transfer device 13 and accommodated in the carrier C, which ends the series of processes of the substrate processing for the single sheet of substrate W.

FIG. 11 is a flowchart showing a processing sequence in the plating processing according to the exemplary embodiment. First, the controller 91 performs the cleaning processing on the substrate W (process S201). In this case, the rotation motor 523 is first driven to rotate the substrate W at a predetermined rotational speed. Then, the nozzle arm 57 located at the retreat position is moved to the discharge position above the center of the substrate W.

Subsequently, the cleaning liquid L2 is supplied from the cleaning liquid nozzle 541 to the substrate W being rotated, so that the surface of the substrate W is cleaned. As a result, deposits and the like adhering to the substrate W are removed from the substrate W. The cleaning liquid L2 supplied to the substrate W is drained into the drain duct 581.

Thereafter, the controller 91 performs the rinsing processing on the substrate W (process S202). In this case, the rinse liquid L3 is supplied from the rinse liquid nozzle 551 to the substrate W being rotated, so that the surface of the substrate W is rinsed. As a result, the cleaning liquid L2 remaining on the substrate W is washed away. The rinse liquid L3 supplied to the substrate W is drained into the drain duct 581.

Then, the controller 91 supplies the plating liquid L onto the substrate W to accumulate the plating liquid L1 on the substrate W (process S203). That is, the controller 91 forms the puddle of the plating liquid L1 on the substrate W.

Next, the controller 91 covers the substrate W with the cover body 6 (process S204). As a result, the space around the substrate W is closed by the cover body 6.

Thereafter, the controller 91 heats the puddle of the plating liquid L1 formed on the substrate W (process S205). Specifically, the controller 91 operates the heater 63 to heat the plating liquid L1 accumulated on the substrate W.

Then, the controller 91 performs the cover body retreating processing of retreating the cover body 6 from the vicinity of the substrate W (process S206). Specifically, the controller 91 operates the cover body moving mechanism 7 to move the cover body 6 from the vicinity of the substrate W to the preset retreat position.

Afterwards, the controller 91 performs the rinsing processing on the substrate W (process S207). In this case, first, the cover body 6 is retreated from above the substrate W. Subsequently, the rotation motor 523 is driven to rotate the substrate W at a predetermined rotational speed.

Then, the rinse liquid L3 is supplied from the rinse liquid nozzle 551 to the substrate W being rotated, so that the surface of the substrate W is rinsed. As a result, the plating liquid L1 remaining on the substrate W is washed away. The rinse liquid L3 supplied to the substrate W is drained into the drain duct 581.

Subsequently, the substrate W after being subjected to the rinsing processing is subjected to the drying processing (process S208). For example, the rotational speed of the substrate W is increased from the rotational speed in the rinsing processing (process S107) to rotate the substrate W at a high speed. As a result, the rinse liquid L3 remaining on the substrate W is shaken off, and the substrate W is dried. Thus, the series of processes of the plating processing for the single sheet of substrate W are completed.

A substrate processing method according to the exemplary embodiment includes a preparation process (process S101), a removing process (process S102), and a metal layer forming process (process S105). In the preparation process (process S101), the substrate W having the first metal layer (seed layer M1) formed on the front surface Wa thereof is prepared. In the removing process (process S102), at least a part of the first metal layer (seed layer M1) formed on the peripheral portion Wc of the substrate W is removed. In the metal layer forming process (process S105), the second metal layer (plating layer) is precipitated on the front surface Wa of the substrate W by using the first metal layer (seed layer M1) as a catalyst after the removing process (process S102). Therefore, uniformity of the film thickness of the plating layer formed on the substrate W can be improved.

Further, in the substrate processing method according to the exemplary embodiment, the removing process (process S102) is performed by discharging the removing liquid L4 capable of removing the first metal layer (seed layer M1) onto the rear surface Wb of the substrate W. Therefore, the uniformity of the film thickness of the plating layer formed on the substrate W can be further improved.

Moreover, in the substrate processing method according to the exemplary embodiment, the removing liquid L4 is an aqueous solution containing hydrogen peroxide and at least one selected from sulfuric acid, hydrofluoric acid, organic acid and ammonia. Thus, the seed layer M1 adhering to the bevel portion of the substrate W or the like in a non-uniform manner can be efficiently removed.

In addition, the substrate processing method according to the exemplary embodiment further includes a rinsing process (process S103) and a drying process (process S104). In the rinsing process (process S103), the rinse liquid L3 is discharged to the rear surface Wb of the substrate W to clean the substrate W after the removing process (process S102). In the drying process (process S104), the substrate W is dried after the rinsing process (process S103). As a result, the appropriate plating layer can be formed in a plating processing.

Moreover, in the substrate processing method according to the exemplary embodiment, an inert gas is discharged to the front surface Wa of the substrate W during the removing process (process S102), the rinsing process (process S103), and the drying process (process S104). As a result, the appropriate plating layer can be formed in the plating processing.

In addition, in the substrate processing method according to the exemplary embodiment, the first metal layer (seed layer M1) has one element selected from copper, cobalt, tungsten, ruthenium, and nickel as a main component. Thus, it is possible to form various kinds of plating layers by the electroless plating processing.

In the substrate processing method according to the exemplary embodiment, the second metal layer (plating layer) has one element selected from copper, cobalt, ruthenium, and nickel as a main component. Thus, it is possible to efficiently form the wiring or the like on the substrate W by various kinds of plating layers.

In the substrate processing method according to the exemplary embodiment, the removing process (process S102) and the metal layer forming process (process S105) are performed within one and the same processing unit. Accordingly, the overall processing time for the substrate W can be shortened.

Moreover, in the substrate processing method according to the exemplary embodiment, the removing process (process S102) and the metal layer forming process (process S105) are performed in different processing units. Accordingly, the uniformity of the film thickness of the plating layer formed on the substrate W can be improved.

So far, the exemplary embodiment of the present disclosure has been described. However, the present disclosure is not limited to the above-described exemplary embodiment, and various changes and modifications may be made without departing from the spirit of the present disclosure.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Substrate processing apparatus (an example of a plating apparatus)
4: Seed layer removing unit
5: Plating unit (an example of a metal layer forming unit)
41: First nozzle (an example of a removing liquid discharge unit)
42: Second nozzle (an example of a removing liquid discharge unit)
52: Substrate holder
91: Controller
L3: Rinse liquid
L4: Removing liquid
M1: Seed layer (an example of a first metal layer)
W: Substrate
Wa: Front surface
Wb: Rear surface
Wc: Peripheral portion

1. A substrate processing method, comprising:
preparing a substrate having a first metal layer formed on a front surface thereof;
removing at least a part of the first metal layer formed on a peripheral portion of the substrate; and
precipitating a second metal layer on the front surface of the substrate by using the first metal layer as a catalyst after the removing of at least the part of the first metal layer.

2. The substrate processing method of claim 1,
wherein the removing of at least the part of the first metal layer is performed by discharging a removing liquid configured to remove the first metal layer to a rear surface of the substrate.

3. The substrate processing method of claim 2,
wherein the removing liquid is an aqueous solution containing hydrogen peroxide and at least one selected from sulfuric acid, hydrofluoric acid, organic acid, and ammonia.

4. The substrate processing method of claim 1, further comprising:
cleaning the substrate by discharging a rinse liquid to a rear surface of the substrate after the removing of at least the part of the first metal layer; and
drying the substrate after the cleaning of the substrate.

5. The substrate processing method of claim 4,
wherein an inert gas is discharged to a front surface side of the substrate during the removing of at least the part of the first metal layer, the cleaning of the substrate, and the drying of the substrate.

6. The substrate processing method of claim 1,
wherein the first metal layer has one element selected from copper, cobalt, tungsten, ruthenium, and nickel as a main component.

7. The substrate processing method of claim 1,
wherein the second metal layer has one element selected from copper, cobalt, ruthenium, and nickel as a main component.

8. The substrate processing method of claim 1,
wherein the removing of at least the part of the first metal layer and the precipitating of the second metal layer are performed in one and a same processing unit.

9. The substrate processing method of claim 1,
wherein the removing of at least the part of the first metal layer and the precipitating of the second metal layer are performed in different processing units.

10. A substrate processing apparatus, comprising:
a substrate holder configured to hold a substrate to be rotated;
a removing liquid discharge unit configured to discharge a removing liquid configured to remove a first metal layer to a rear surface of the substrate;
a metal layer forming unit configured to form a second metal layer on a front surface of the substrate; and
a controller configured to control the substrate holder, the removing liquid discharge unit and the metal layer forming unit,
wherein the controller controls the substrate holder to hold the substrate having the first metal layer formed on the front surface thereof, controls the removing liquid discharge unit to remove at least a part of the first metal layer formed on a peripheral portion of the substrate, and controls the metal layer forming unit to precipitate the second metal layer on the front surface of the substrate by using the first metal layer as a catalyst.

11. A computer-readable recording medium having stored thereon computer-executable instructions that, in response to execution, cause a substrate processing apparatus to perform a substrate processing method as claimed in claim 1.
